(19) United States
(12) Patent Application Publication
(10) Pub. No.: US 2019/0386158 A1
(43) Pub. Date: Dec. 19, 2019

(54) PLASMA-CURING OF LIGHT-RECEIVING SURFACES OF SOLAR CELLS

(71) Applicants: SunPower Corporation, San Jose, CA (US); Total Marketing Services, Puteaux (FR)

(72) Inventors: Taiqing Qiu, Los Gatos, CA (US); Emeline Soichi, San Francisco, CA (US); Périne Jaffrennou, Mountain View, CA (US)

(21) Appl. No.: 16/464,074

(22) PCT Filed: Dec. 13, 2017
(86) PCT No.: PCT/US2017/066159

§ 371 Date: May 24, 2019

Related U.S. Application Data
(60) Provisional application No. 62/435,628, filed on Dec. 16, 2016.

(51) Int. Cl. H01L 31/0216; H01L 31/0224; H01L 31/0236; H01L 31/0352; H01L 31/18

(52) U.S. Cl. CPC H01L 31/02168; H01L 31/022441; H01L 31/186; H01L 31/035281; H01L 31/03529; H01L 31/02363

(57) ABSTRACT

Methods of fabricating solar cells using plasma-curing of light-receiving surfaces of the solar cells, and the resulting solar cells, are described. In an example, a method of fabricating a solar cell includes forming a dielectric layer on a light-receiving surface of a silicon substrate. The method also includes forming an anti-reflective coating (ARC) layer over the dielectric layer. The method also includes exposing the ARC layer to plasma-induced radiation.

### TECHNICAL FIELD

Embodiments of the present disclosure are in the field of renewable energy and, in particular, plasma-curing of light-receiving surfaces of solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIGS. 1A-IF illustrate cross-sectional views of various stages in a method of fabricating a solar cell, in accordance with an embodiment.

FIG. 2 is a flowchart listing operations in a method of fabricating a solar cell, in accordance with an embodiment.

FIG. 3 illustrates a cross-sectional view of a back-contact solar cell having emitter regions formed over a back surface of a substrate and having a plasma-cured and thermally annealed ARC layer over a light-receiving surface of the substrate, in accordance with an embodiment.

FIG. 4 illustrates a cross-sectional view of a back-contact solar cell having emitter regions formed over a back surface of a substrate and having a plasma-cured and thermally annealed ARC layer over a light-receiving surface of the substrate, in accordance with an embodiment.

FIG. 5 is a plot demonstrating UV stability for solar cells having undergone plasma-curing versus solar cells not having undergone plasma-curing, in accordance with an embodiment.

FIG. 6 illustrates cross-sectional views of various stages in a method of fabricating a solar cell having an intermediate layer, such as a Si-rich, SiN, or intrinsic or doped amorphous Si layer, in accordance with an embodiment.

FIGS. 7A-7F illustrate cross-sectional views of various stages in the fabrication of a hybrid solar cell, in accordance with an embodiment.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing manufacture speed of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

Methods of fabricating solar cells using plasma-curing of light-receiving surfaces of the solar cells, and the resulting solar cells, are described. In the following description, numerous specific details are set forth, such as specific process flow operations, in order to provide a thorough understanding of embodiments of the present disclosure. It will be apparent to one skilled in the art that embodiments of the present disclosure can be practiced without these specific details. In other instances, well-known fabrication techniques, such as lithography and patterning techniques, are not described in detail in order to not unnecessarily obscure embodiments of the present disclosure. Furthermore, it is to be appreciated that the various embodiments shown in the figures are illustrative representations and are not necessarily drawn to scale.

Methods of fabricating solar cells are disclosed. In one embodiment, a method of fabricating a solar cell includes growing a phosphorous-doped oxide layer and an anti-reflective coating (ARC) layer in a plasma-enhanced chemical vapor deposition (PECVD) tool. The layers can be formed with or without a thin transition layer, such as a silicon-rich, silicon nitride, or amorphous silicon layer, between the phosphorous-doped oxide layer and the ARC layer. That is, the ARC layer can be formed directly on the phosphorous-doped oxide layer. The method also includes exposing the ARC layer to plasma-induced radiation. A resulting plasma-cured solar cell can have improved front surface field (FSF) performance for solar cells. For example, one or more embodiments, when implemented, improve the ultraviolet (UV) performance and/or stability of the solar cell.

To provide context, light-induced degradation (LID) and/or UV degradation pose long-standing issues for the long-term stability of solar cell performance. LID and UV degradation is the degradation of solar cell over time observed under light exposure such as exposure to sunlight or light-soaking conditions. UV stability can be critical for performance guarantees and for product quality differentiation. More particularly, UV stability can be critical to an ongoing performance and efficiency of high-efficiency solar cells. Accordingly, efforts have been made to improve the stability of solar cells, i.e., to reduce LID and UV degradation.

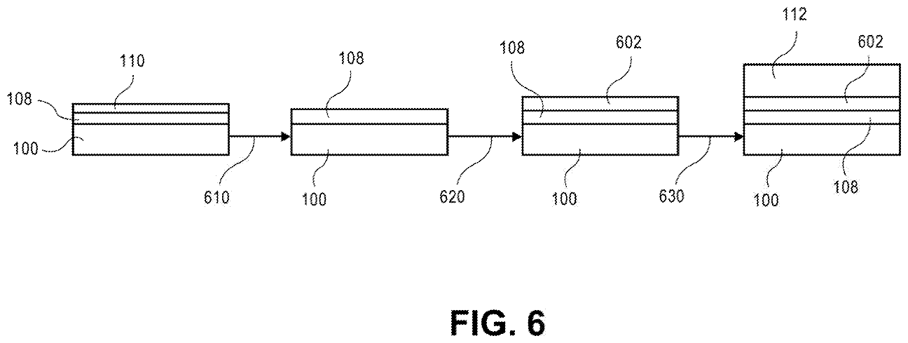

Current attempts to limit LID and UV degradation include cell-level and module-level solutions. At the cell-level, a front surface of the solar cell can be passivated and capped with an ARC, e.g., a silicon nitride (SiN or SiN:H) coating. The silicon nitride coating can be formed over an interfacial layer, such as a Si-rich, a SiN, or an amorphous Si layer, at a silicon/thermal oxide (c-Si/TOX) interface (FIG. 6). At the module-level, an encapsulant with UV blocker placed above the solar cell can block UV light. Research has found that the above-mentioned cell-level solution can still experience LID and UV degradation over time, presumably caused by hot electron injection across the c-SiTOX interface which breaks existing Si—H bonds. The hot electron can be trapped in the subsequent layers and be re-excited to bounce back and forth across the interface, which is a process known as interface wear. The above-mentioned module-level solution further limits performance of the solar module by limiting a total amount of irradiation available for energy conversion at the solar cell.

Addressing one or more of the above issues, in accordance with one or more embodiments described, UV performance of a solar cell is improved by performing a plasma-curing operation. In one exemplary embodiment, the plasma-curing operation can be performed in the PECVD tool used to form an ARC layer of the solar cell. The plasma-curing operation can be performed under controlled conditions as an additional operation within the PECVD tool, and can follow the ARC recipe on the front surface of the solar cell. The plasma-curing operation can eliminate a need for PSG dry etch as well as the interfacial layer under the ARC layer, and thus, can provide a simplified cell manufacturing process. Furthermore, since the manufacturing process is simplified, i.e., requires fewer operations and materials, and because the manufacturing process does not require specialized equipment, i.e., the PECVD tool can perform the plasma-curing, an overall manufacturing cost can be reduced.

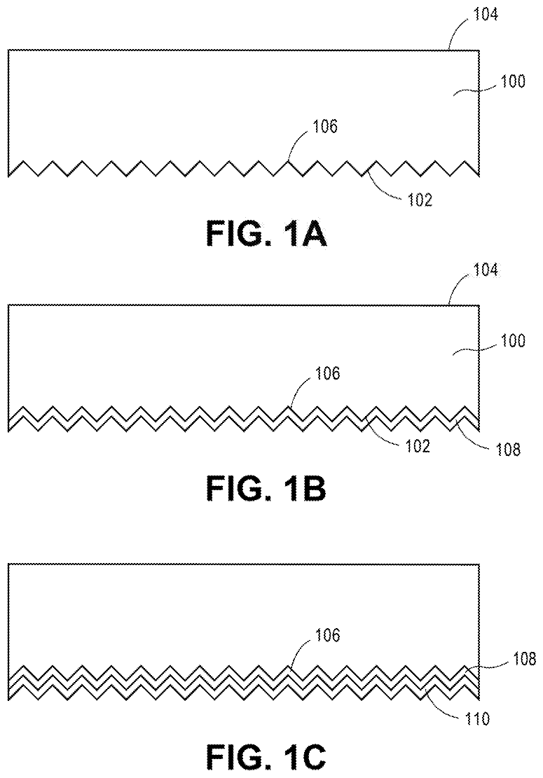

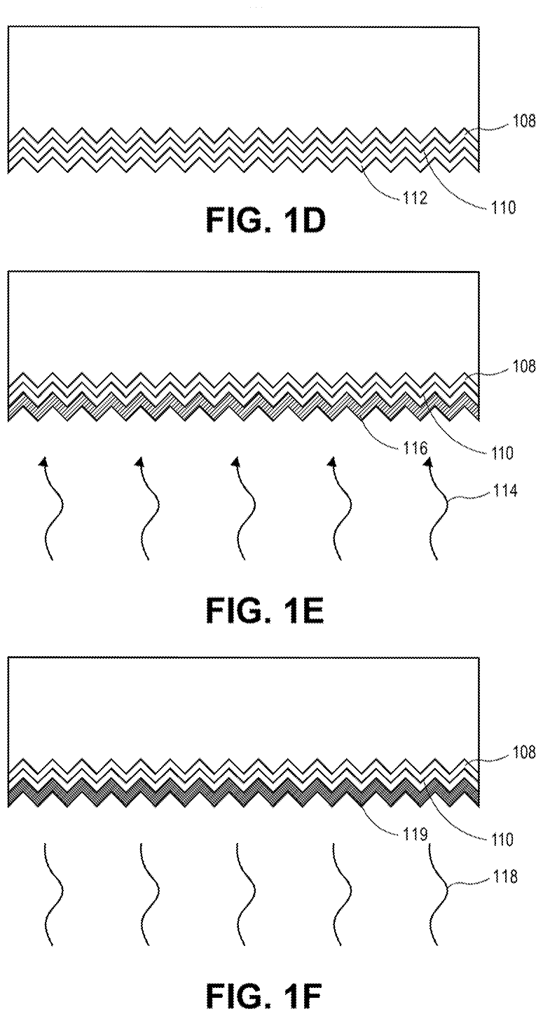

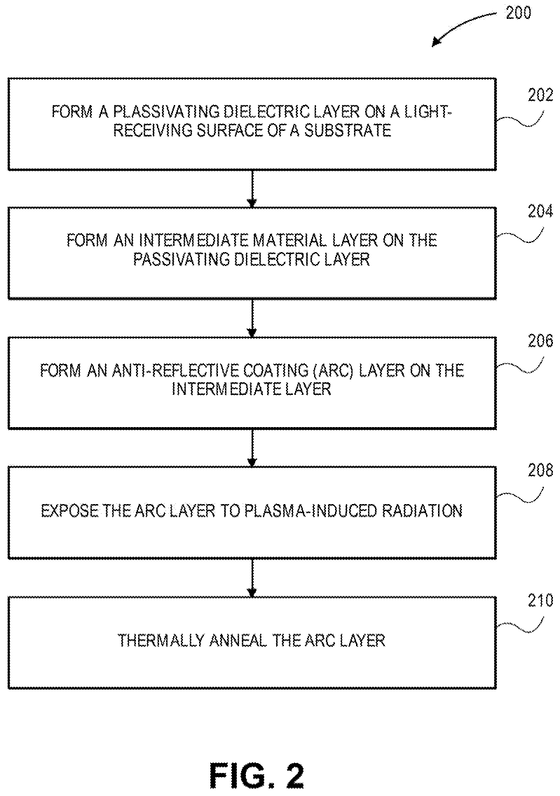

Referring to FIGS. 1A-1F, cross-sectional views of various stages in a method of fabricating a solar cell are shown in accordance with an embodiment. FIG. 2 includes a flowchart 200 listing operations in a method of fabricating a solar cell corresponding to FIGS. 1A-1F. Accordingly, FIGS. 1A-2 are described in combination below.

Referring to FIG. 1A, a starting substrate of a solar cell is illustrated. The substrate 100 can have a light-receiving surface 102 and a back surface 104. In an embodiment, the substrate 100 is a monocrystalline silicon substrate, such as a bulk single crystalline N-type or P-type doped silicon substrate. It is to be appreciated, however, that substrate 100 can be a layer, such as a multi-crystalline, N-type, or P-type silicon substrate. Light-receiving surface 102 can be smooth. In an embodiment, however, the light-receiving surface 102 has a texturized topography 106. In one such embodiment, a hydroxide-based wet etchant is employed to texturize the front surface of the substrate 100. It is to be appreciated that a texturized surface can be one which has a regular or an irregular shaped surface for scattering incoming light, decreasing the amount of light reflected off of the light-receiving surfaces of the solar cell.

FIG. 1B illustrates the structure of FIG. 1A following formation of a passivating dielectric layer on a light-receiving surface of the substrate. Referring to FIG. 1B and corresponding operation 202 of flowchart 200, a passivating dielectric layer 108 is formed on the light-receiving surface 102 of substrate 100. In one embodiment, the passivating dielectric layer 108 is conformal with the light-receiving surface 102. For example, dielectric layer 108 can conform to texturized topography 106, as is depicted in FIG. 1B.

In an embodiment, the passivating dielectric layer 108 is a layer of silicon dioxide (SiO₂). In one such embodiment, the layer of silicon dioxide (SiO₂) has a thickness in the range of 10-400 Angstroms. In one embodiment, the passivating dielectric layer 108 is hydrophilic. In an embodiment, the passivating dielectric layer 108 is formed by a technique such as, but not limited to, chemical oxidation of a portion of the light-receiving surface 102 of the silicon substrate 100, PECVD of silicon dioxide (SiO₂), thermal oxidation of a portion of the light-receiving surface 102 of the silicon substrate 100, atomic layer deposition (ALD) of SiO₂, or exposure of the light-receiving surface 102 of the silicon substrate 100 to ultra-violet (UV) radiation in an O₂ or O₃ environment. In a specific embodiment, the passivating dielectric layer 108 is a thermal silicon oxide layer formed on the light-receiving surface 102 of an N-type monocrystalline silicon substrate 100. In another specific embodiment, the passivating dielectric layer 108 is formed by atomic layer deposition (ALD), and is a silicon oxide passivating dielectric layer.

FIG. 1C illustrates the structure of FIG. 1B following formation of an intermediate material layer on the passivating dielectric layer. Referring to FIG. 1C and corresponding operation 204 of flowchart 200, an intermediate material layer(s) 110 is formed on the passivating dielectric layer 108. In one embodiment, as is depicted in FIG. 1C, the intermediate material layer(s) 110 is conformal with the texturized topography 106. In an embodiment, the intermediate material layer(s) 110 is or includes a phosphorous-doped oxide layer. The phosphorous-doped oxide layer can include P₂O₅ and can be formed by thermal oxidation of a portion of the light-receiving surface of silicon substrate 100.

FIG. 1D illustrates the structure of FIG. 1C following formation of an ARC layer on the intermediate material layer 110. Referring to FIG. 1D and corresponding operation 206 of flowchart 200, an ARC layer 112 is formed on the intermediate material layer(s) 110. It is to be appreciated that the intermediate material layer(s) 110 can be omitted and, in one embodiment, the ARC layer 112 is formed directly on the passivating dielectric layer 108. In either case, ARC layer 112 is formed over dielectric layer 108. As is depicted in FIG. 1D, the ARC layer 112 can be conformal with the texturized topography 106.

ARC layer 112 can be formed in a PECVD tool. PECVD tools are known in the art to perform PECVD deposition processes. More particularly, a PECVD tool can include a deposition chamber to hold a reacting gas. An ARC-forming plasma of the reacting gas can be generated in the chamber by RF frequency or DC discharge between a pair of electrodes. That is, the electrodes can be powered with high-frequency electromagnetic waves to generate the plasma from the reacting gas. A thin film, i.e., ARC layer 112, can be deposited from the energized gas state of the ARC-forming plasma to a solid state on substrate 100 within the PECVD tool. More particularly, ARC layer 112 can be deposited from the ARC-forming plasma onto intermediate material layers 110.

In an embodiment, the ARC layer 112 is a non-conductive dielectric layer. In one such embodiment, the non-conductive ARC layer is or includes a silicon nitride layer (SiN). In a particular such embodiment, the silicon nitride is formed at a temperature less than 500 degrees Celsius. In another such embodiment, the ARC layer 112 is or includes a layer of aluminum oxide (AlOₓ). In another embodiment, the ARC layer 112 is a conductive ARC layer. In one such embodiment, the conductive ARC layer includes a layer of indium tin oxide (ITO).

FIG. 1E illustrates the structure of FIG. 1D following exposure of the ARC layer to plasma-induced radiation. Referring to FIG. 1E and corresponding operation 208 of flowchart 200, the ARC layer 112 is exposed to plasma-induced radiation 114. In an embodiment, the exposure of the ARC layer 112 to the plasma-induced radiation 114 forms a plasma-cured ARC layer 116. More particularly, plasma-induced radiation 114 converts ARC layer 112 into plasma-cured ARC layer 116

Plasma-curing of ARC layer 112 can be performed in the same PECVD tool used to deposit ARC layer 112. That is, the ARC layer 112 can be exposed to plasma-induced radiation in the chamber of the PECVD tool used to form ARC layer 112. For example, the chamber can be filled with a reacting gas to form an energized plasma. The reacting gas can be the same reacting gas as is used to form ARC layer 112, or the reacting gas used to form plasma-induced radiation 114 can be different. That is, the energized plasma can be a same or a different plasma than the ARC-forming plasma.

By way of example, the reacting gas used to induce radiation 114 can be N₂, NH₃, Ar, He, H₂, or a combination thereof. Accordingly, the energized plasma can be one or more of an N₂ plasma, an NH₃ plasma, or an Ar plasma. The energized plasma can produce a light exposure of different intensities for individual wavelengths. For example, the plasma can produce a high-intensity UV light. The reacting gas can be selected based on a radiation that the reacting gas emits when energized to create a plasma. For example, N₂ and Ar provide strong UV emissions, i.e., generate plasma-induced UV photons, with high energy and can be selected as a plasma-curing gas for that reason. In an embodiment, the energized plasma can radiate photons having a wavelength in a range of 100-1200 nm, e.g., 250-450 nm. Accordingly, exposing the ARC layer 112 to plasma-induced radiation 114 can involve exposing the ARC layer 112 to photons radiated by the energized plasma, and having a wavelength in the range of 100-1200 nm, e.g., 250-450 nanometers. Plasma also creates energetic ion and electron bombardments on ARC surfaces. The bombardments can modify microscopic structures of the ARC film, such as bonding or loosening hydrogen in the film.

The energized plasma can have a plasma pressure in a range of 100 mT to 20 Torr, e.g., 1 Torr. On the other hand, the plasma can be generated at atmospheric pressure. More particularly, in an embodiment, plasma curing is performed in a separate tool from the PECVD tool used to form ARC layer 112, as described below. Other process parameters can be controlled, such as plasma power density, or a temperature of the wafer during plasma treatment. For example, plasma power density can be maintained in a range of 0.05-1 W/cm². By way of example, such a power density can be achieved by the PECVD tool using 0.5 to 10 kW RF power at 13.56 MHz. DC plasma, lower frequency plasma (e.g., 400 kHz), higher frequency plasma (e.g., 27 MHz), or microwave plasmas can also be used. Wafer temperature can be maintained in a range from room temperature to 500 degrees Celsius during plasma-curing. For example, wafer temperature can be maintained at ambient temperature, e.g., 20-25 degrees Celsius, or higher.

Tools for generating atmospheric plasma can be less expensive than PECVD tools, and thus, the plasma curing operation of FIG. 1E can be performed in a different tool, or in a different stage of a cluster tool, than the PECVD tool used for the ARC layer formation operation of FIG. 1D. In an embodiment, a cluster tool can be used to combine many of the above described process operations in a single pass in a process tool. For example, in one such embodiment, the cluster tool can include several distinct PECVD operations in one or more PECVD tools to form passivating dielectric layer 108, intermediate material layer 110, and ARC layer 112. The cluster tool can also include a plasma-induced radiation operation within one of the PECVD tools or in a separate atmospheric plasma chamber. The various operations can be performed at different stages of the tool, and the solar cell can be moved through the stages sequentially, e.g., by a conveyor belt, linear actuator, rotary actuator, etc. To minimize tool footprint, an atmospheric plasma head can be integrated onto wafer loading and handling stations.

Plasma exposure duration can be controlled in the PECVD tool or the atmospheric plasma tool. In an embodiment, exposing the ARC layer 112 to plasma-induced radiation 114 involves exposing the ARC layer 112 to the plasma-induced radiation 114 for a duration in the range of 1-1800 seconds. For example, exposing the ARC layer 112 to plasma-induced radiation can include exposing the ARC layer 112 for a duration in a range of 1-60 seconds, e.g., 30 seconds or less.

In an embodiment, subsequent to plasma-curing of ARC layer 112, the solar cell is thermally annealed. Referring to FIG. 1F and corresponding operation 210 of flowchart 200, the plasma-cured ARC layer 116 is thermally annealed, e.g., with thermal heating. In an embodiment, the thermal heating of the plasma-cured ARC layer 116 forms a UV-cured and thermally annealed ARC layer 119. The plasma-cured ARC layer 116 can be thermally annealed by heating the ARC layer 116 to a temperature in a range of 200-500° C., e.g., 300° C. In an embodiment, the ARC layer is thermally annealed using a process such as, but not limited to, a forming gas anneal (FGA) process, e.g., under N₂, a thermal anneal (RTA) process, an intra-red (IR) heating process, a furnace heating process, and a laser annealing process. The thermal annealing can release H from the H source of ARC layer 116 to improve passivation. In accordance with an embodiment, the thermal annealing is performed subsequent to curing the ARC layer using plasma-induced radiation 114. Alternatively, the thermal annealing is performed at substantially the same time as curing the ARC layer 116 using plasma-induced radiation 114.

It is to be appreciated that the above described nexus between the cross-sectional views of FIGS. 1A-IF and the flowchart of FIG. 2 is an exemplary embodiment of the method illustrated in the flowchart 200 of FIG. 2. However, embodiments of the flowchart 200 of FIG. 2 are not so limited.

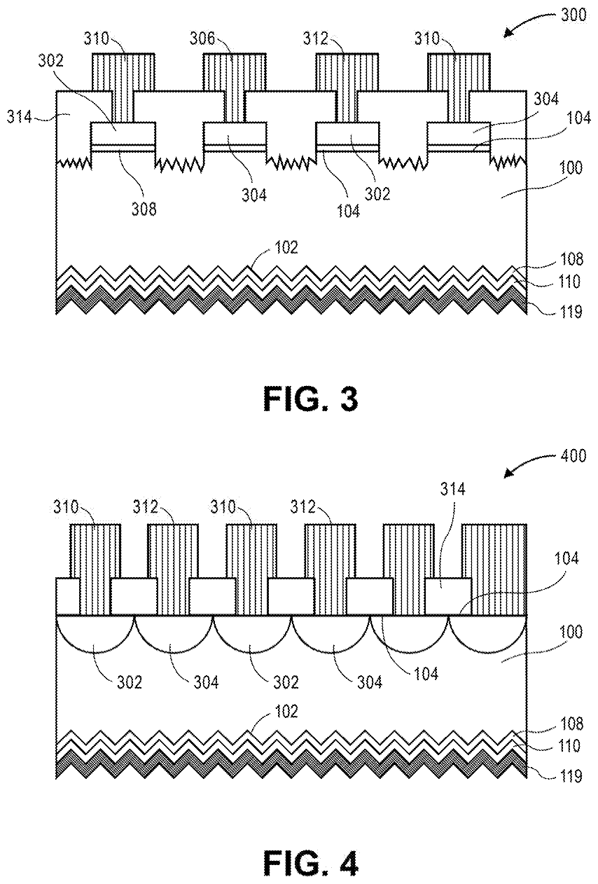

Referring to FIG. 3, a cross-sectional view of a back-contact solar cell having emitter regions formed over a back surface of a substrate and having a plasma-cured and thermally annealed ARC layer over a light-receiving surface of the substrate is shown in accordance with an embodiment. A solar cell 300 includes a silicon substrate 100 having a light-receiving surface 102. A dielectric layer 108 is disposed on the light-receiving surface 102 of the silicon substrate 100. An intermediate material layer(s) 110 is disposed on the dielectric layer 108. A plasma-cured and thermally annealed ARC layer 119 is disposed on the intermediate material layer(s) 110, as shown, or is disposed on the dielectric layer 108. The stack of layers on the light-receiving surface 102 of the solar cell 300 can be the same or substantially the same as described in association with FIGS. 1A-IF.

On the back surface 104 of the substrate 100, alternating P-type 302 and N-type 304 emitter regions are formed. In one such embodiment, trenches 306 are disposed between the alternating P-type 302 and N-type 304 emitter regions. More particularly, in an embodiment, first polycrystalline silicon emitter regions 304 are formed on a first portion of a thin dielectric layer 308 and are doped with an N-type impurity. Second polycrystalline silicon emitter regions 302 are formed on a second portion of the thin dielectric layer 308 and are doped with a P-type impurity. In an embodiment the tunnel dielectric 308 is a silicon oxide layer having a thickness of 2 nanometers or less.

Conductive contact structures 310/312 are fabricated by first depositing and patterning an insulating layer 314 to have openings and then forming one or more conductive layers in the openings. The conductive contact structures 310/312 can include metal and can be formed by a deposition, lithographic, and etch approach or, alternatively, a printing or plating process or, alternatively, a foil or wire adhesion process.

Referring to FIG. 4, a cross-sectional view of a back-contact solar cell having emitter regions formed over a back surface of a substrate and having a UV-cured and thermally annealed ARC layer over a light-receiving surface of the substrate is shown in accordance with an embodiment. Solar cell 400 includes a silicon substrate 100 having a light-receiving surface 102. A dielectric layer 108 is disposed on the light-receiving surface 102 of the silicon substrate 100. An optional intermediate material layer(s) 110 is disposed on the dielectric layer 108. A plasma-cured and thermally annealed ARC layer 119 is disposed on the intermediate material layer(s) 110, as shown, or is disposed on the passivating dielectric layer 108. The stack of layers on the light-receiving surface of the solar cell 400 of FIG. 4 can be the same or substantially the same as described in association with FIGS. 1A-1E.

Within the back surface 104 of the substrate 100, alternating P-type 302 and N-type 304 emitter regions are formed. More particularly, in an embodiment, first emitter regions 302 are formed within a first portion of substrate 100 and are doped with an N-type impurity. Second emitter regions 304 are formed within a second portion of substrate 100 and are doped with a P-type impurity. Conductive contact structures 310/312 are fabricated by first depositing and patterning an insulating layer 314 to have openings and then forming one or more conductive layers in the openings. The conductive contact structures 310/312 can include metal and can be formed by a deposition, lithographic, and etch approach or, alternatively, a printing or plating process or, alternatively, a foil or wire adhesion process.

In an embodiment, the fabrication of the conductive contacts 310/312 involves the inclusion of one or more sputtered, plated or bonded conductive layers. In an embodiment, the conductive contacts 310/312 are formed by first forming a metal seed layer on the exposed portions of the alternating P-type 302 and N-type 304 emitter regions. In one such embodiment, a mask is first formed to expose only select portions of the alternating P-type 302 and N-type 304 emitter regions in order to direct the metal seed layer formation to restricted locations.

In an embodiment, the metal seed layer is an aluminum-based metal seed layer. In an embodiment, the metal seed layer includes a layer having a thickness in the range of 0.05 to 20 μm and includes aluminum in an amount greater than 90 atomic %. In an embodiment, the metal seed layer is deposited as a blanket layer which is later patterned, e.g., using a deposition, lithographic, and etch approach. In another embodiment, the metal seed layer is deposited as patterned layer. In one such embodiment, the patterned metal seed layer is deposited by printing the patterned metal seed layer.

In an embodiment, contact formation further includes forming a metal layer by plating on the metal seed layer to form the conductive contacts 310/312. In an embodiment, the metal layer is a copper layer. Accordingly, the conductive contacts 310/312 can be formed by first forming a metal seed layer and then performing an electroplating process.

In another embodiment, the conductive contacts 310/312 are formed by printing a paste. The paste can be composed of a solvent and the aluminum/silicon (Al/Si) alloy particles. A subsequent electroplating or electroless-plating process can then be performed. The paste can be formed in addition to, or in place of, the metal seed layer.

In another embodiment, the conductive contacts 310/312 are formed by first forming the metal seed layer and then adhering a metal foil layer to the metal seed layer. In one such embodiment, the metal foil is an aluminum (Al) foil having a thickness in the range of 5-100 μm. In one embodiment, the Al foil is an aluminum alloy foil including aluminum and second element such as, but not limited to, copper, manganese, silicon, magnesium, zinc, tin, lithium, or combinations thereof. In one embodiment, the Al foil is a temper grade foil such as, but not limited to, F-grade (as fabricated), O-grade (full soft), H-grade (strain hardened) or T-grade (heat treated). In one embodiment, the aluminum foil is an anodized aluminum foil. In an embodiment, the metal foil is welded to the metal seed layer. The metal foil can subsequently be patterned, e.g., by laser ablation and/or etching.

In another embodiment, a metal wire is formed on the metal seed layer. In one such embodiment, the wire is an aluminum (Al) or copper (Cu) wire. In an embodiment, the metal wire is welded to the metal seed layer.

Exposing a solar cell to plasma treatment during manufacturing improves UV degradation properties of a front surface, i.e., the surface having light-receiving surface 102. As described below, this has been demonstrated by reliability testing of solar cell samples. Accordingly, plasma-cured ARC layer 116 and/or plasma-cured and thermally annealed ARC layer 119 can provide UV stability in the field.

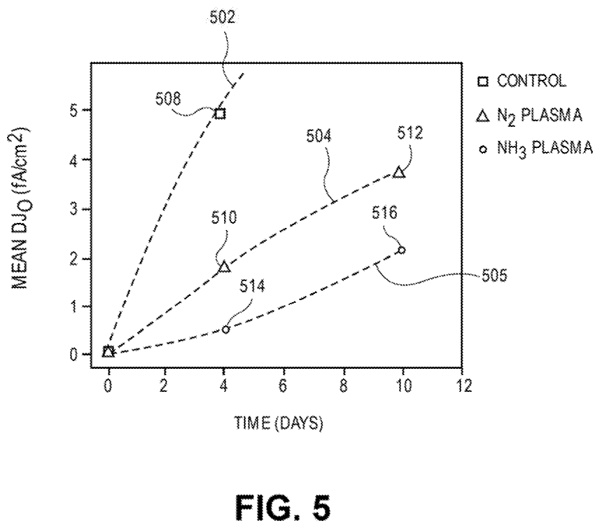

Referring to FIG. 5, a plot demonstrating UV stability for samples having undergone plasma-curing versus samples not having undergone plasma-curing is shown in accordance with an embodiment. Reliability testing of solar cells can include an accelerated method of performing UV exposure of the solar cell to evaluate module power loss over time. The test can be performed on a solar cell for a few days or weeks to extrapolate UV degradation over a longer period of time, e.g., 25 years. The plot of FIG. 5 graphs a change in Delta J₀ over time. J₀ is reverse saturation current density. Physically, reverse saturation current is a measure of the “leakage” of carriers across the p-n junction in reverse bias. This leakage is a result of carrier recombination in the neutral regions on either side of the junction. UV degradation can cause a change in this leakage.

The change in Delta J₀ is shown for a control solar cell without plasma curing 502 and for test solar cells 504 and 505, e.g., a solar cell 300 or solar cell 400, having undergone plasma-curing by irradiation from photons emitted by a plasma in a PECVD chamber. Test solar cell 504 corresponds to a solar cell plasma-cured using an N₂ plasma, and test solar cell 505 corresponds to a solar cell plasma-cured using an NH₃ plasma. The comparison of the accelerated UV test results show that the test cells have lower UV degradation than the control cell: after 4 days of UV stability testing, the control solar cell 502 has a mean change 508 in Delta J₀ of approximately 5 fA/cm². By contrast, the test solar cell 504 has a mean change 510 in Delta J₀ of approximately 1.5 fA/cm² after 4 days of accelerated UV testing and a mean change 512 in Delta J₀ of approximately 4 fA/cm² after 10 days of accelerated UV testing. Similarly, the test solar cell 505 has a mean change 514 in Delta J₀ of approximately 0.5 fA/cm² after 4 days of accelerated UV testing and a mean change 516 in Delta J₀ of approximately 2 fA/cm² after 10 days of accelerated UV testing. Accordingly, UV stability testing has shown that solar cells irradiated by photons emitted by an N₂ and an NH₃ plasma in a PECVD chamber have better UV stability than non-plasma-cured solar cells. Thus, plasma treatment of solar cells improves UV stability of a front-surface structure of solar cells 300, 400.

Although certain materials are described specifically with reference to above described embodiments, some materials can be readily substituted with others. By way of example, referring again to FIGS. 1F, 3, and 4, the intermediate material layer 110 can be a layer including, but not limited to, an N-type micro-crystalline silicon layer, an N-type polycrystalline silicon layer, an amorphous silicon (a-Si) layer, a silicon-rich silicon nitride layer, or a Group III-V material layer (such as GaP, AlGaP, GaAs, InGaAs, GaN or AlGaN). In an embodiment, the intermediate material layer 110 is a plasma-cured and thermally annealed layer or stack of layers. In an embodiment, the dielectric layer 108 is a plasma-cured and thermally annealed passivating dielectric layer. In an embodiment, a different material substrate, such as a group III-V material substrate, can be used instead of a silicon substrate. Furthermore, it is to be appreciated that, where the ordering of N+ and then P+ type doping is described specifically for emitter regions 302, 304 on a back surface 104 of a solar cell, other embodiments contemplated include the opposite ordering of conductivity type, e.g., P+ and then N+ type doping, respectively.

Although reference is made significantly to back contact solar cell arrangements, it is to be appreciated that the described approaches can have application to front contact solar cells or bi-facial architectures as well. For example, the laminate structure having plasma-cured and thermally annealed ARC layer 119 may be on a back surface of the solar cell. That is, ARC layer 119 may be a backside anti-reflection coating (BARC) layer 119. It is also to be appreciated that both front side and back side surfaces of any such solar cells can benefit from a UV cure process.

The above described approaches can be applicable to manufacturing of other than solar cells. For example, the methods described above can be leveraged for the manufacturing of electronic products outside of the solar industry, where is it desirable to minimize performance degradation from exposure to light. By way of example, light detectors, UV detectors, and light emitting diode (LEDs) or products incorporating LEDs, e.g., displays, can benefit from the plasma-curing approaches described above.

Plasma-cured solar cells have certain advantages, which have been described in part above, and will be expanded on here. Implementation of plasma curing processes does not require additional tooling to obtain improved UV stability. Accordingly, plasma curing processes do not induce heavy capital expenditures and tool development given that the curing processes can be performed in an existing tool, i.e., a PECVD tool used to form dielectric layer 108 and intermediate material layer 110. Furthermore, the method of fabricating solar cells using plasma-curing can simplify the front surface of the solar cell by removing several steps in forming the ARC structure. The simplification can reduce manufacturing costs. To further illustrate the referred-to simplification, an alternative method of forming a solar cell is described below by way of comparison.

Referring to FIG. 6, cross-sectional views of various stages in a method of fabricating a solar cell having a Si-rich intermediate layer is shown in accordance with an embodiment. As shown in FIGS. 1A-1C, a dielectric layer 108, e.g., an SiO₂ layer, and an intermediate material layer 110, e.g., a P₂O₅ layer, can be formed on a substrate 100, e.g., a silicon substrate. In an embodiment, the intermediate layer 110 can be etched to remove the layer and expose the underlying dielectric layer 108. For example, intermediate layer 110 can be removed by an etching operation performed within a PECVD tool at operation 610. In an embodiment, a second intermediate layer 602 can be deposited onto dielectric layer 108. Second intermediate layer 602 can be a Si-rich layer deposited via PECVD at operation 620. For example, second intermediate layer 602 can be deposited within the PECVD chamber used to plasma-cure the solar cell. At operation 630, an ARC layer 112 can be deposited over second intermediate layer 602 in a same manner as described with respect to FIG. 1D. For example, ARC layer 112 can be deposited via PECVD at operation 630. It will be appreciated that the final structure of FIG. 6 has an intermediate layer between ARC layer 112 and dielectric layer 108, similar to the structure of FIG. 1D. In the case of FIG. 6, however, the intermediate layer is a Si-rich layer rather than a P₂O₅ layer, by way of example. Furthermore, several additional steps are required to advance from the initial structure to the final structure of FIG. 6, as compared to the simplified process to advance to the structure of FIG. 1D. More particularly, the method described with respect to FIGS. 1A-ID eliminate an etching operation, i.e., to remove intermediate layer 110, and a bottom layer deposition operation, i.e., to deposit second intermediate layer 602.

The simplified structure fabricated from the method of FIGS. 1A-ID provides several benefits. First, elimination of the P₂O₅ etch operation shown in FIG. 6 can eliminate etching damage and the resulting degradation of front-surface passivation that such an operation introduces. Accordingly, the method of FIGS. 1A-ID can improve surface passivation and open circuit voltage. Second, removing second intermediate layer 602, e.g., the Si-rich bottom layer, from the solar cell structure can allow more light to reach the silicon substrate 100, which can in turn increase short-circuit current. By increasing the open circuit voltage and short-circuit current, cell efficiency can be increased. Such improvement in cell performance can also translate into an improved levelized cost of energy and/or an extension of the product warranty term, or fewer warranty claims.

Although the structure and method of FIG. 6 is more complex than the counterparts of FIGS. 1A-1D, it has been shown that UV stability of the final structure of FIG. 6 can be improved by plasma-curing and thermal annealing as described above with respect to FIGS. 1E-1F. That is, the final structure of FIG. 6 can be plasma-cured and thermally annealed to convert ARC layer 112 into ARC layer 119, and the resulting solar cell exhibits improved UV stability. Accordingly, improved UV stability can be achieved for both complex and simplified solar cell structures using the manufacturing methods described above.

Thus, methods of fabricating solar cells using plasma-curing of light-receiving surfaces of the solar cells, and the resulting solar cells, have been disclosed.

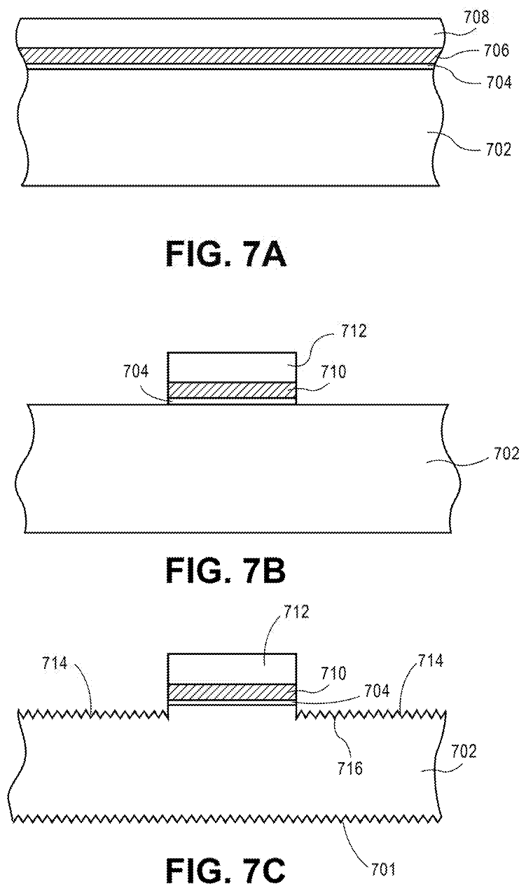

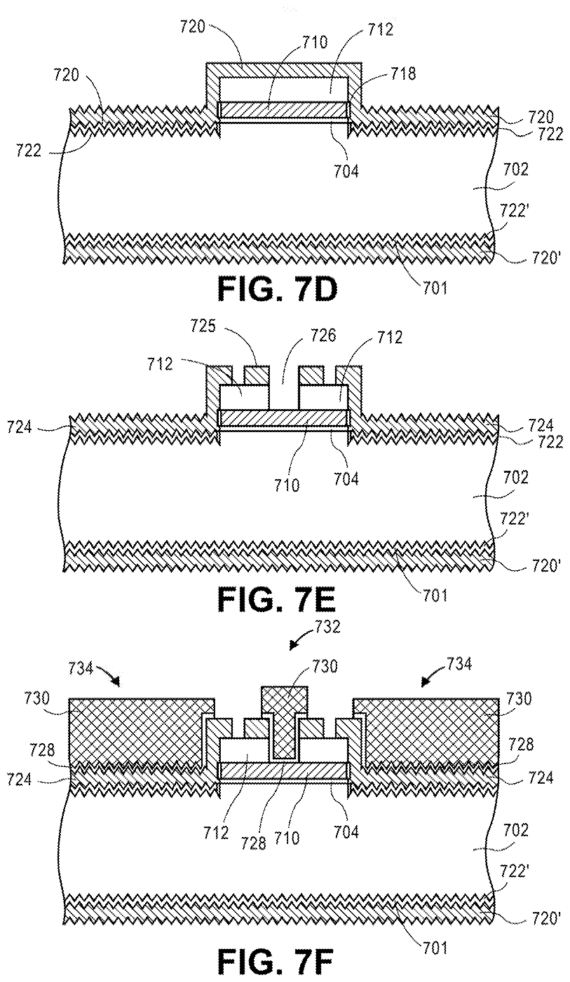

Referring to FIGS. 7A-7F, cross-sectional views of various stages in the fabrication of a hybrid solar cell, in accordance with an embodiment of the present disclosure. A hybrid, or differentiated, solar cell architecture includes N-type and P-type emitter regions that are structurally different. The hybrid solar cell may include one or more ARC layers that are plasma-cured and/or thermally annealed according to the structural and processing embodiments described above. Accordingly, it will be understood that the following description introduces another type of solar cell that includes one or more surfaces that can be plasma-treated to enhance UV stability of the solar cell.

Referring to FIG. 7A, a method of fabricating alternating N-type and P-type emitter regions of a solar cell involves forming a first silicon layer 706 of a first conductivity type on a first thin dielectric layer 704 formed on a back surface of a substrate 702.

In an embodiment, the substrate 702 is a monocrystalline silicon substrate, such as a bulk single crystalline N-type doped silicon substrate. It is to be understood, however, that substrate 702 may be a layer, such as a multi-crystalline silicon layer, disposed on a global solar cell substrate. In an embodiment, the first thin dielectric layer 704 is a thin oxide layer such as a tunnel dielectric silicon oxide layer having a thickness of approximately 2 nanometers or less.

In an embodiment, the first silicon layer 706 is a polycrystalline silicon layer that is doped to have the first conductivity type either through in situ doping, post deposition implanting, or a combination thereof. In a specific embodiment, the second conductivity type is P-type (e.g., formed using boron impurity atoms).

An insulating layer 708 is formed on the first silicon layer 706. In an embodiment the insulating layer 708 includes silicon dioxide.

Referring to FIG. 7B, the insulating layer 708 and the first silicon layer 706 are patterned to form a first silicon region 710 of the first conductivity type having an insulating cap 712 thereon. In an embodiment, a lithographic or screen print masking and subsequent etch process is used to pattern the insulating layer 708 and the first silicon layer 706. In another embodiment, a laser ablation process (e.g., direct write) is used to pattern the insulating layer 708 and the first silicon layer 706. In either case, in one embodiment, the first thin dielectric layer 704 is also patterned in the process, as is depicted in FIG. 7B.

Referring to FIG. 7C, optionally, recesses 714 may be formed in the substrate 702 during (or subsequent to) the patterning of the insulating layer 708 and the first silicon layer 706. Furthermore, in one embodiment, the surfaces 716 of the recesses 714 are texturized. In a same or similar process, a light receiving surface 701 of the substrate 702 may also be texturized, as is depicted in FIG. 7C. In an embodiment, a hydroxide-based wet etchant is used to form at least a portion of the recesses 714 and/or to texturize exposed portions of the substrate 702. A texturized surface may be one which has a regular or an irregular shaped surface for scattering incoming light, decreasing the amount of light reflected off of the light-receiving and/or exposed surfaces of the solar cell. It is to be appreciated, however, that the texturizing of the back surface and even the recess formation may be omitted from the process flow.

Referring to FIG. 7D and corresponding operation 508 of flowchart 500, a second thin dielectric layer 718 is formed on exposed sides of the first silicon regions 710. In an embodiment, the second thin dielectric layer 718 is formed in an oxidation process and is a thin oxide layer such as a tunnel dielectric silicon oxide layer having a thickness of approximately 2 nanometers or less. In another embodiment, the second thin dielectric layer 718 is formed in a deposition process and is a thin silicon nitride layer or silicon oxynitride layer. As is explained below in more detail, in one embodiment, the dielectric layers (e.g., the first thin dielectric layer 704, the second thin dielectric layer 718) are amorphous dielectric layers formed by oxidation of a silicon substrate.

Referring again to FIG. 7D and now to corresponding operation 510 of flowchart 500, a second silicon layer 720 of a second, different, conductivity type is formed on a third thin dielectric layer 722 formed on the back surface of the substrate 702, and on the second thin dielectric layer 718 and the insulating cap 712 of the first silicon regions 710. Corresponding thin dielectric layer 722′ and second silicon layer 720′ of the second conductivity type may also be formed on the light-receiving surface 701 of the substrate 702, is same or similar process operations, as is depicted in FIG. 7D. Additionally, although not depicted, an ARC layer may be formed on the corresponding second silicon layer 720′. The ARC layer may correspond to a plasma-cured and thermally annealed ARC layer as described above.

In an embodiment, the third thin dielectric layer 722 is formed in an oxidation process and is a thin oxide layer such as a tunnel dielectric silicon oxide layer having a thickness of approximately 2 nanometers or less. In an embodiment, the second silicon layer 720 is a polycrystalline silicon layer that is doped to have the second conductivity type either through in situ doping, post deposition implanting, or a combination thereof. In a specific embodiment, the second conductivity type is N-type (e.g., formed using phosphorus atoms or arsenic impurity atoms).

Referring to FIG. 7E, the second silicon layer 720 is patterned to form isolated second silicon regions 724 of the second conductivity type and to form a contact opening 726 in regions of the second silicon layer 720 above the insulating cap 712 of the first silicon regions 710. In an embodiment, discrete regions of silicon 725 may remain as an artifact of the patterning process. In an embodiment, a laser ablation process is used to pattern the second silicon layer 720.

Referring again to FIG. 7E, the insulating cap 712 is patterned through the contact openings 726 to expose portions of the first silicon regions 710. In an embodiment, the insulating cap 712 is patterned using a laser ablation process. For example, in one embodiment, a first laser pass is used to pattern the second silicon layer 720, including forming contact opening 726. A second laser pass in the same location as contact opening 726 is the used to pattern the insulating cap 712.

Referring to FIG. 7F, a metal seed layer 728 is formed on the exposed portions of the first silicon regions 710 and on the isolated second silicon regions 724. A metal layer 730 is plated on the metal seed layer to form conductive contacts 732 and 734, respectively, for the first silicon regions 710 and the isolated second silicon regions 724. In an embodiment, the metal seed layer 728 is an aluminum-based metal seed layer, and the metal layer 730 is a copper layer. In an embodiment, a mask is first formed to expose only the exposed portions of the first silicon regions 710 and the isolated second silicon regions 724 in order to direct the metal seed layer 728 formation to restricted locations.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims can be formulated during prosecution of the present application (or an application claiming priority thereto) to any such combination of features. In particular, with reference to the appended claims, features from dependent claims can be combined with those of the independent claims and features from respective independent claims can be combined in any appropriate manner and not merely in the specific combinations enumerated in the appended claims.

What is claimed is:

1. A method of fabricating a solar cell, the method comprising:
forming a dielectric layer on a light-receiving surface of a silicon substrate;
forming an anti-reflective coating (ARC) layer over the dielectric layer; and
exposing the ARC layer to plasma-induced radiation.

2. The method of claim 1, wherein exposing the ARC layer to plasma-induced radiation comprises exposing the ARC layer to photons radiated by one or more of an energized plasma or an ion/electron bombardment, and wherein the photons have a wavelength in a range of 100-1200 nanometers.

3. The method of claim 2, wherein exposing the ARC layer to plasma-induced radiation includes exposing the ARC layer for a duration in a range of 1 to 1800 seconds at a pressure in a range of 0.1-20 Torr.

4. The method of claim 2, wherein forming the ARC layer includes depositing the ARC layer over the dielectric layer in a chamber of a plasma-enhanced chemical vapor deposition (PECVD) tool using an ARC-forming plasma in the chamber.

5. The method of claim 4, wherein the ARC layer is exposed to plasma-induced radiation in the chamber of the PECVD tool, and wherein the energized plasma is a different plasma than the ARC-forming plasma.

6. The method of claim 2, wherein the energized plasma is one or more of an N₂ plasma, an NH₃ plasma, an H₂ plasma, or an Ar plasma.

7. The method of claim 1 further comprising plasma curing the ARC layer at a temperature in a range of ambient to 500 degrees Celsius.

8. The method of claim 2, wherein exposing the ARC layer to plasma-induced radiation is performed in one or more of a PECVD deposition chamber or a load lock chamber.

9. The method of claim 2, wherein exposing the ARC layer to plasma-induced radiation includes exposing the ARC layer to atmospheric plasma in one or more of a wafer loading station or an exchange station.

10. The method of claim 2, wherein the plasma-induced radiation is generated using one or more of DC power, KHz power, MHz RF power, or GHz microwave power, and wherein a frequency of the power is selected based on a relative impact of UV/light radiation and ion/electron bombardment on the ARC layer.

11. A method of fabricating a solar cell, the method comprising:
forming a dielectric layer on a light-receiving surface of a silicon substrate;
forming an anti-reflective coating (ARC) layer over the dielectric layer; and
exposing the ARC layer to a non-plasma-induced radiation.

12. The method of claim 11, wherein the non-plasma-induced radiation includes one or more of a microwave, an RF electromagnetic wave, or an X-ray.

13. A solar cell fabricated according to the method of claim 1.

14. A solar cell, comprising:
a passivating dielectric layer on a light-receiving surface of a silicon substrate; and
an anti-reflective coating (ARC) layer below the passivating dielectric layer, the ARC layer a plasma-cured and thermally annealed ARC layer.

15. The solar cell of claim 14, wherein the ARC layer is a non-conductive ARC layer.

16. The solar cell of claim 14, wherein the ARC layer is a conductive ARC layer.

17. A method of fabricating a solar cell, the method comprising:
forming a dielectric layer on a light-receiving surface of a silicon substrate;
forming a layer over the dielectric layer, the layer comprising a silicon nitride layer (SiN), a layer of aluminum oxide (AlOₓ), or a layer of indium tin oxide (ITO); and
exposing the layer to plasma-induced radiation.

18. The method of claim 17, wherein exposing the layer to plasma-induced radiation comprises exposing the layer to photons radiated by one or more of an energized plasma or an ion/electron bombardment, and wherein the photons have a wavelength in a range of 100-1200 nanometers.

19. The method of claim 18, wherein exposing the layer to plasma-induced radiation includes exposing the ARC layer for a duration in a range of 1 to 1800 seconds at a pressure in a range of 0.1-20 Torr.

20. The method of claim 18, further comprising plasma curing the layer at a temperature in a range of ambient to 500 degrees Celsius.
